(19) United States
(12) Patent Application Publication
(10) Pub. No.: US 2024/0247405 A1
(43) Pub. Date: Jul. 25, 2024

(54) METHOD FOR CONTROLLING LAYER-TO-LAYER THICKNESS IN MULTI-TIER EPITAXIAL PROCESS

(71) Applicant: Applied Materials, Inc., Santa Clara, CA (US)

(72) Inventors: Alexandros ANASTASOPOULOS, San Francisco, CA (US); Zuoming ZHU, Sunnyvale, CA (US); Maribel MALDONADO-GARCIA, Valle de Santiago (MX); Thomas KIRSCHENHEITER, Tempe, AZ (US); Flora Fong-Song CHANG, Saratoga, CA (US)

(21) Appl. No.: 18/100,978

(22) Filed: Jan. 24, 2023

(51) Int. Cl. C30B 25/22; C30B 15/14; C30B 25/12; C30B 25/16; C30B 29/06; C30B 29/08

(52) U.S. Cl. CPC C30B 25/22; C30B 15/14; C30B 25/12; C30B 25/16; C30B 29/06; C30B 29/08

(57) ABSTRACT

A method for substrate processing includes flowing one or more process reactive gases into an upper volume of a processing chamber, flowing cleaning gas into a lower volume of the processing chamber, measuring temperature of an inner surface of the lower volume of the processing chamber, and adjusting temperature of the inner surface of the lower volume of the processing chamber, based on the measured temperature.

### BACKGROUND

### Field

Embodiments described herein generally relate to semiconductor device fabrication, and more particularly, to methods and systems for multi-tier epitaxial deposition processes.

### Description of the Related Art

An inflection in dynamic random access memory (DRAM) technology is expected with the transition from a two-dimensional (2D) to a three-dimensional (3D) architecture. This transition is needed in order to meet the ever-growing demand for DRAM density (Gb/mm²).

A key step in the semiconductor manufacturing process of these 3D devices is epitaxial deposition of a stack of alternating Si and SiGe layers. These alternating layers can typically extend in height of more than 100 pairs. Each one of these layers must meet strict requirements in terms of its individual thickness.

A drift in the chamber thermal environment during the deposition of the stack could be responsible for an out-of-bound excursion of each layer thickness. This can be captured by chamber sensors like temperature and power traces.

Therefore, there is a need for methods and systems that reduce a drift in the chamber thermal environment during a multi-tier epitaxial deposition process.

### SUMMARY

Embodiments of the present disclosure provide a method for substrate processing. The method includes flowing one or more process reactive gases into an upper volume of a processing chamber, flowing cleaning gas into a lower volume of the processing chamber, measuring temperature of an inner surface of the lower volume of the processing chamber, and adjusting temperature of the inner surface of the lower volume of the processing chamber, based on the measured temperature.

Embodiments of the present disclosure also provide a method for substrate processing. The method includes performing an epitaxial deposition process to deposit layers on a surface of a substrate supported on a front surface of a substrate support disposed in an upper volume of a processing chamber, and performing a coating removal process to remove coating on an inner surface of a lower volume of the processing chamber, wherein the lower volume is on the opposite side of the substrate support from the front surface.

Embodiments of the present disclosure further provide a substrate processing system. The substrate processing system includes a processing chamber including an upper window, a lower window, a substrate support disposed between the upper window and the lower window, a process volume between a front surface of the substrate support and the upper window, a purge volume between a back surface of the substrate support and the lower window, and a temperature sensor disposed on the lower window, a controller including instructions that, when executed, cause operations to be conducted, the operations including performing an epitaxial deposition process to deposit layers on a surface of a substrate supported on the front surface of the substrate support, performing a coating removal process to remove coating on an inner surface of the lower window, performing a temperature monitoring process to measure temperature of an inner surface of the lower window, and performing a temperature control process to adjust temperature of the inner surface of the lower window, based on the measured temperature.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic cross-sectional view of a system for substrate processing, according to one implementation.

FIG. 2 is a schematic block diagram view of a method for controlling layer-to-layer thickness in a multi-tier epitaxial process, according to some embodiments.

FIG. 3A depicts a temperature variation comparison of an exemplary multi-tier epitaxial growth process.

FIG. 3B depicts a system power comparison to provide to heat sources to control temperature of an exemplary multi-tier epitaxial growth process.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The embodiments described herein provide systems and methods of multi-tier epitaxial deposition with a mitigated drift in a chamber thermal environment, leading to reduced layer-to-layer non-uniformity in a deposited stack of alternating Si and SiGe layers. The drift in the chamber thermal environment is reduced by controlling temperature and flow of gases at a lower volume of the chamber.

Current baseline multi-tier epitaxial processes use a pyrometer disposed in an upper volume of the chamber for controlling a substrate temperature. This adds an inherent instability to the temperature control, since the signal from the pyrometer is influenced by growing layers. In addition, a small amount of deposition gases may leak into the lower volume of the chamber and form a coating on the lower volume of the chamber. The signal from a pyrometer disposed in the lower volume of the chamber is influenced by the coating, and thus controlling a substrate temperature by the pyrometer at the lower volume also introduces an instability to the temperature control.

In the embodiments described herein, the temperature control uses a pyrometer disposed in the lower volume of the chamber, while a large amount of cleaning gas and/or purge gas is flowed into the lower volume of the chamber to maintain the lower volume of the chamber free from coating. With the combination of these two operations, the inherent instability with respect to the temperature control is removed.

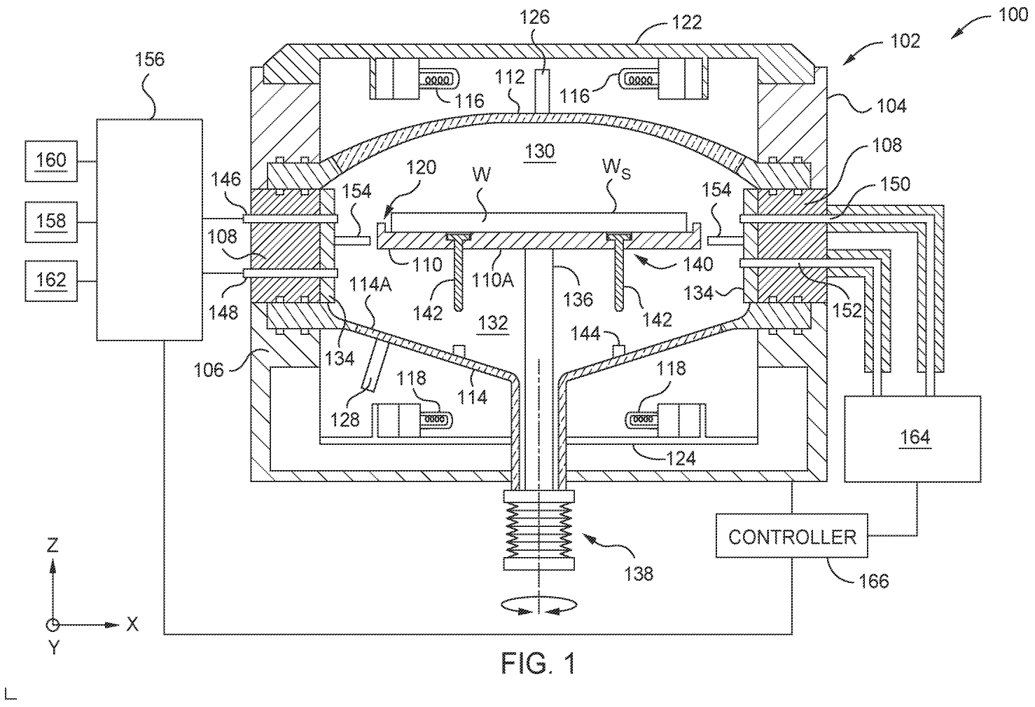

FIG. 1 is a schematic cross-sectional view of a system 100 for substrate processing, according to one implementation. The system 100 includes a processing chamber 102. In one or more embodiments, the processing chamber 102 is a deposition chamber. In one embodiment, which can be combined with other embodiments, the processing chamber 102 is an epitaxial deposition chamber. The processing chamber 102 is utilized to grow an epitaxial film on a substrate W. The processing chamber 102 creates a cross-flow of precursors across a surface Wₛ of the substrate W to deposit a film.

The processing chamber 102 includes an upper body 104, a lower body 106 disposed below the upper body 104, and a flow module 108 disposed between the upper body 104 and the lower body 106. The upper body 104, the flow module 108, and the lower body 106 form a chamber body. Disposed within the chamber body is a substrate support 110, an upper window 112 (such as an upper dome), a lower window 114 (such as a lower dome), upper heat sources 116, and lower heat sources 118.

The substrate support 110 is disposed between the upper window 112 and the lower window 114. The substrate support 110 includes a front surface 120 that faces the upper window 112 and supports the substrate W. The upper heat sources 116 are disposed between the upper window 112 and a lid 122. The lower heat sources 118 are disposed between the lower window 114 and a floor 124. The upper window 112 is an upper dome and is formed of an energy transmissive material, such as quartz. The lower window 114 is a lower dome and is formed of an energy transmissive material, such as quartz.

In the implementation shown in FIG. 1, the heat sources 116, 118 are lamps. Other heat sources are contemplated, such as resistive heaters, light emitting diodes (LEDs), and/or lasers.

The processing chamber 102 may include one or more temperature sensors 126, 128, such as optical pyrometers, which measure temperatures within the processing chamber 102. The temperature sensor 126 (e.g., a top pyrometer) may be disposed on an upper side of the upper window 112. The temperature sensor 128 (e.g., a bottom pyrometer) may be disposed on a lower side of the lower window 114.

A process volume (also referred to as an “upper volume”) 130 and a purge volume (also referred to as a “lower volume”) 132 are formed between the upper window 112 and the lower window 114. The process volume 130 and the purge volume 132 are part of an internal volume defined at least partially by the upper window 112, the lower window 114, and one or more liners 134.

The internal volume has the substrate support 110 disposed therein. The purge volume 132 is on the opposite of the substrate support 110 from the front surface 120 and a substrate W disposed thereon. The substrate support 110 is attached to a shaft 136. The shaft 136 is connected to a motion assembly 138. The motion assembly 138 includes one or more actuators and/or adjustment devices that provide movement and/or adjustment for the shaft 136 and/or the substrate support 110 within the processing volume 130.

The substrate support 110 may include lift pin holes 140 disposed therein. The lift pin holes 140 are sized to accommodate a lift pin 142 for lowering and/or lifting of the substrate W from the substrate support 110 before and/or after a deposition process is performed. The lift pins 142 may rest on lift pin stops 144 when the substrate support 110 is lowered from a process position to a transfer position.

The flow module 108 includes a process inlet passage 146 in fluid communication with the process volume 130, and a purge inlet passage 148 in fluid communication with the purge volume 132. The flow module 108 further includes a process outlet passage 150 in fluid communication with the process volume 130, and a purge outlet passage 152 in fluid communication with the purge volume 132. The process inlet passages 146 and the purge inlet passage 148 are disposed on the opposite side of the flow module 108 from the process outlet passage 150 and the purge outlet passage 152. One or more flow guides 154 are disposed below the process inlet passage 146 and the process outlet passage 150. The one or more flow guides 154 are disposed above the purge inlet passage 148. In one or more embodiments, the one or more flow guides 154 include a pre-heat ring. One or more liners 134 are disposed on an inner surface of the flow module 108 and protect the flow module 108 from reactive gases used during deposition operations and/or cleaning operations. The process inlet passage 146 and the purge inlet passage 148 are each positioned to flow a gas parallel to the surface Wₛ of a substrate W disposed within the process volume 130. The process inlet passage 146 and the purge inlet passage 148 are fluidly connected to a gas supply system 156 which coordinates the gases to be delivered to the processing chamber 102. One or more process gas sources 158, one or more cleaning gas sources 160, and one or more purge gas sources 162 are fluidly connected to the gas supply system 156. In one or more embodiments, the one or more process gas sources 158 include one or more reactive gas sources and one or more carrier gas sources.

The process outlet passage 150 and the purge outlet passage 152 are fluidly connected to an exhaust pump 164 (e.g., a vacuum pump).

One or more process gases supplied to the gas supply system 156 using the one or more process gas sources 158 can include one or more reactive gases (such as one or more of silicon (Si), phosphorus (P), and/or germanium (Ge)) and/or one or more carrier gases (such as one or more of nitrogen (N₂) and/or hydrogen (H₂)). One or more purge gases supplied using the one or more purge gas sources 162 can include one or more inert gases (such as one or more of hydrogen (H₂), argon (Ar), helium (He), and/or nitrogen (N₂)). One or more cleaning gases supplied using the one or more cleaning gas sources 160 can include one or more of hydrogen (H₂) and/or chlorine (Cl). In one embodiment, which can be combined with other embodiments, the one or more process gases include silicon phosphide (SiP) and/or phosphine (PH₃), and the one or more cleaning gases include hydrochloric acid (HCl). The present disclosure contemplates that the carrier gas(es), purge gas(es), and/or cleaning gas(es) are all candidates for recycling described herein.

As shown, the system 100 includes a controller 166 in communication with the processing chamber 102. The controller 166 is used to control processes and methods, such as the operations of the methods described herein. The controller 166 is in communication with the exhaust pump 164 and the gas supply system 156. The controller 166 controls the exhausted gas (exhausted from the processing chamber 102) using sensors disposed along the exhaust pump 164, and/or the gas supply system 156. By monitoring the purity content of the gas, the controller 166 can control the gas supply system 156 and determine (and control) where gas(es) flow in the system 100.

The controller 166 includes a central processing unit (CPU), a memory containing instructions, and support circuits for the CPU. The controller 166 controls various items directly, or via other computers and/or controllers. In one or more embodiments, the controller 166 is communicatively coupled to dedicated controllers, and the controller 166 functions as a central controller.

The controller 166 is of any form of a general-purpose computer processor that is used in an industrial setting for controlling various substrate processing chambers and equipment, and sub-processors thereon or therein. The memory, or non-transitory computer readable medium, is one or more of a readily available memory such as random access memory (RAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)), read only memory (ROM), floppy disk, hard disk, flash drive, or any other form of digital storage, local or remote. The support circuits of the controller 166 are coupled to the CPU for supporting the CPU (a processor). The support circuits include cache, power supplies, clock circuits, input/output circuitry and subsystems, and the like. Operational parameters (the pressure of a recycled gas, the purity of a recycled gas, the chemical makeup of a recycled gas) and operations are stored in the memory as a software routine that is executed or invoked to turn the controller 166 into a specific purpose controller to control the operations of the various systems/chambers/recycling systems/modules described herein. The controller 166 is configured to conduct any of the operations described herein. The instructions stored on the memory, when executed, cause one or more of operations of method 200 (described below) to be conducted.

The various operations described herein can be conducted automatically using the controller 166, or can be conducted automatically and/or manually with certain operations conducted by a user.

The controller 166 is configured to adjust output to controls of the system 100 based off of sensor readings, a system model, and stored readings and calculations. The controller 166 includes embedded software and a compensation algorithm to calibrate measurements. The controller 166 can include one or more machine learning algorithms and/or artificial intelligence algorithms that estimate optimized parameters for deposition operation(s), purge operation(s), and/or cleaning operation(s). The one or more machine learning algorithms and/or artificial intelligence algorithms can use, for example, a regression model (such as a linear regression model) or a clustering technique to estimate optimized parameters. The algorithm can be unsupervised or supervised.

In one or more embodiments, the gas supply system 156 is responsible for providing all gases to the processing chamber 102 regardless which gas source 158, 160, 162 supplies the gases. The gas supply system 156 is controlled by the controller 166.

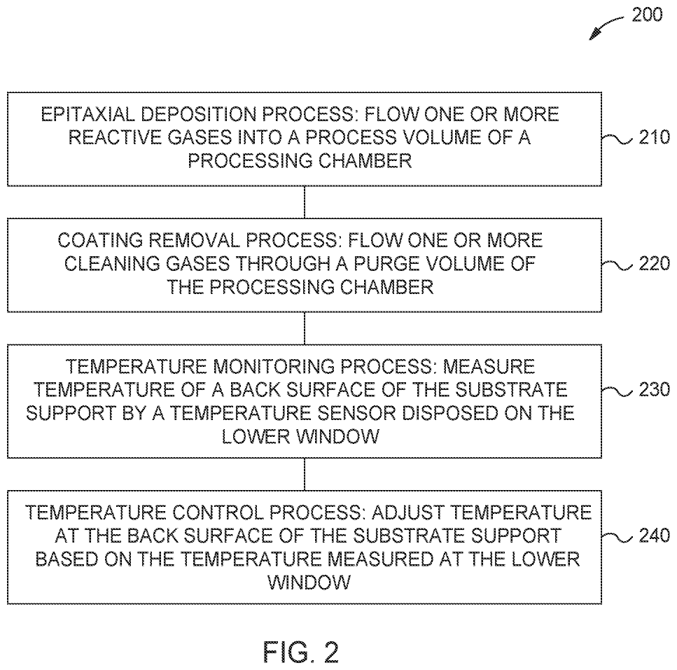

FIG. 2 is a schematic block diagram view of a method 200 for controlling layer-to-layer thickness in a multi-tier epitaxial process, using a substrate processing system, such as the system 100 shown in FIG. 1, according to some embodiments.

The method 200 begins with block 210, in which an epitaxial deposition process is performed to deposit layers on a surface Wₛ of a substrate W supported on the front surface 120 of the substrate support 110 disposed in the process volume 130 of the processing chamber 102. The epitaxial deposition process includes flowing one or more reactive gases from the one or more process gas sources 158 into the process volume 130 of the processing chamber 102. The one or more reactive gases enter the process volume 130 via the process inlet passage 146 above the one or more flow guides 145 and exit via the process outlet passage 150.

Layers that are deposited in block 210 may be alternating layers of first material (e.g., silicon (Si)) and second material (e.g., silicon germanium (SiGe)).

Each layer may have a thickness of between about 50 Å and about 1000 Å. The number of pairs of layers of the first material and the second material is more than 2.

In some embodiments, the one or more reactive gases include a deposition gas and a carrier gas. The deposition gas includes a silicon or germanium-containing precursor and a dopant source. The dopant source may include a precursor phosphine(PH₃), phosphorus trichloride (PCl₃), triisobutylphosphine ([(CH₃)₃C]₃P), arsine (AsH₃), arsenic trichloride (AsCl₃), tertiarybutylarsine (AsC₄H₁₁), antimony trichloride (SbCl₃), or Sb(C₂H₅)₅, including n-type dopants such as phosphorus (P), arsenic (As), or antimony (Sb). The dopant source may include a precursor diborane (B₂H₆), or trimethylgallium Ga(CH₃)₃, including p-type dopants such as boron (B) or gallium (Ga). The carrier gas may include nitrogen (N₂), argon (Ar), helium (He), or hydrogen (H₂).

During the epitaxial deposition process, a portion of the deposition gas may leak into the purge volume 132 between the flow guide 154 and the substrate support 110 and may form coating on inner surfaces of the purge volume 132 (e.g., a back surface 110A of the substrate support 110 and an inner surface 114A of the lower window 114 as shown in FIG. 1). Since the epitaxial deposition process may be long (e.g., deposition of 100 pairs of silicon (Si) and silicon germanium (SiGe) layers), the coating may accumulate. This coating may cause inaccurate temperature measurement by the temperature sensor 128 (e.g., a bottom pyrometer) disposed on the lower window 114. Thus, this coating is eliminated or prevented in block 220.

In block 220, simultaneously with block 210, a coating removal process is performed to reduce the coating on the inner surfaces of the purge volume 132 (e.g., the back surface 110A of the substrate support 110 and the inner surface 114A of the lower window 114). The coating removal process includes flowing purge gas from the one or more purge gas sources 162 or cleaning gas from the one or more cleaning gas source 160 through the purge volume 132 of the processing chamber 102, via the purge inlet passage 148 and the purge outlet passage 152. The purge gas may include hydrogen (H₂) at a flow rate of more than 2 standard liters per minute (slm), and dilute the portion of the deposition gas flowed into the purge volume 132, preventing formation of a coating on the back surface 110A of the substrate support 110 and the inner surface 114A of the lower window 114. The cleaning gas may include chlorine containing etchant gas, removing the coating that is formed on the back surface 110A of the substrate support 110 and the inner surface 114A of the lower window 114. The purge gas or the cleaning gas may be prevented from leaking into the process volume 130, which may interfere with the epitaxial deposition process, since the purge gas or the cleaning gas flow through the purge volume 132 via the purge inlet passage 148 and the purge outlet passage 152 below the flow guides 154.

In block 230, a temperature monitoring process is performed to measure temperature of the inner surface of the purge volume 132 (e.g., the lower window 114) by the temperature sensor 128 (e.g., a bottom pyrometer) disposed on the lower window 114. The temperature measured at the back surface 110A of the substrate support 110 on the opposite side of the substrate support 110 from a substrate W disposed thereon may not be affected by growth of a film on the substrate W. Further, the temperature measured at the back surface 110A of the substrate support 110 may not be affected by a coating on the back surface 110A of the substrate support 110 or on the inner surface 114A of the lower window 114 as the coating is prevented or eliminated in block 220.

In block 240, a temperature control process is performed to adjust the temperature at the inner surface of the purge volume 132 (e.g., the lower window 114), based on the temperature measured at the inner surface of the purge volume 132 (e.g., the lower window 114) on the opposite side of the substrate support 110 from the substrate W disposed thereon in block 230, by adjusting power provided to the upper heat sources 116 and lower heat sources 118. Various gas flow rates may also be adjusted to control the temperature at the lower window 114.

### Examples

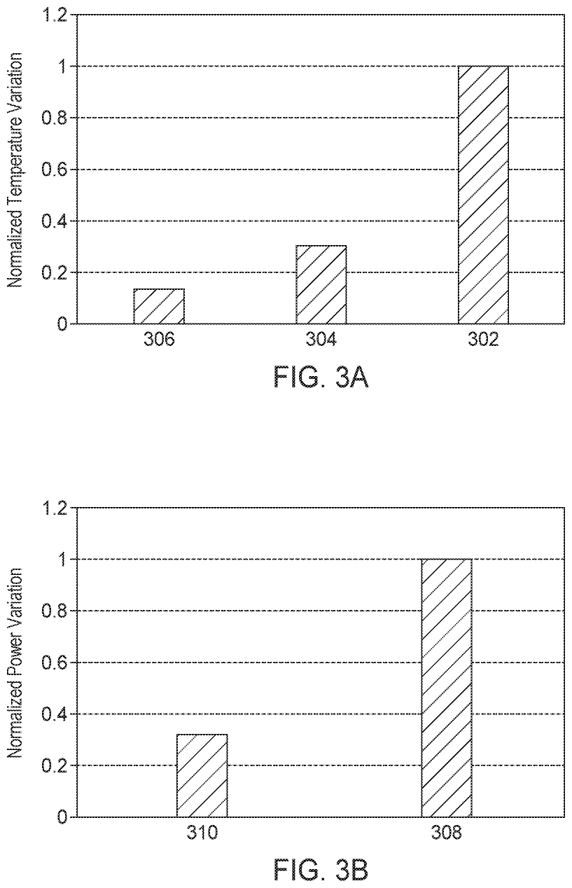

FIG. 3A depicts a temperature variation of an exemplary multi-tier epitaxial growth process, in which temperature is controlled by the temperature sensor 126 (e.g., a top pyrometer) disposed on the upper window 112 and thus the temperature at the upper window 112 is constant. Temperature variation 302 illustrates variation of temperature measured at the back surface of 110 when a coating removal process in block 220 was not performed. Temperature variation 304 illustrates variation of temperature measured at the back surface of 110 when a coating removal process in block 220 was performed where cleaning gas include chlorine containing etchant gas. Since coating is at least partially removed from the inner surface 114A of the lower window 114, the temperature decrease is reduced. Temperature variation 306 illustrates variation of temperature measured at the back surface of 110 when a coating removal process in block 220 was performed where cleaning gas was flowed at a higher flow rate than in the temperature variation 306. The temperature decrease is reduced as compared to the temperature variation 304.

FIG. 3B depicts a system power to provide to the heat sources 116 and 118 to control temperature of an exemplary multi-tier epitaxial growth process. System power variation 308 illustrates system power required to provide to the heat sources 116 and 118 when the temperature is monitored by the temperature sensor 126 (e.g., a top pyrometer) at the upper window 112. System power variation 310 illustrates system power required to provide to the heat sources 116 and 118 when the temperature was monitored by the temperature sensor 128 (e.g., a bottom pyrometer) (as in block 230) disposed on the lower window 114 and the coating on the back surface 110A of the substrate support 110 and the inner surface 114A of the lower window 114 was at least partially removed (as in block 220). Since signal from the temperature sensor 128 (e.g., a bottom pyrometer) is free from interference with an epitaxial growth on a substrate on the substrate support 110 or coating on the back surface 110A of the substrate support 110 and the inner surface 114A of the lower window 114, the power variation is minimal and significantly reduced compared to 308.

The embodiments described herein provide systems and methods of a multi-tier epitaxial deposition with a mitigated drift in the chamber thermal environment. Temperature control uses a temperature sensor disposed on the lower volume of a processing chamber, while a large amount of cleaning gas and/or purge gas is flowed into the lower volume of the chamber to maintain the lower volume of the chamber free from coating. The inherent instability with respect to the temperature control thus is removed, leading to reduced layer-to-layer non-uniformity in a deposited stack of alternating Si and SiGe layers.

While the foregoing is directed to embodiments of the present disclosure, other and further embodiments of the disclosure may be devised without departing from the basic scope thereof, and the scope thereof is determined by the claims that follow.

What is claimed is:

1. A method for substrate processing, comprising:
flowing one or more process reactive gases into an upper volume of a processing chamber;
flowing cleaning gas into a lower volume of the processing chamber;
measuring temperature of an inner surface of the lower volume of the processing chamber; and
adjusting temperature of the inner surface of the lower volume of the processing chamber, based on the measured temperature.

2. The method of claim 1, wherein the flowing of the one or more process reactive gases into the upper volume of the processing chamber and the flowing of the cleaning gas into the lower volume of the processing chamber are performed simultaneously.

3. The method of claim 1, wherein the one or more process reactive gases comprise a silicon or germanium containing precursor.

4. The method of claim 3, wherein layers deposited by the flowing of the one or more process reactive gases comprise more than 2 pairs of alternating layers of silicon (Si) and silicon germanium (SiGe), each layer having a thickness of between 50 Å and 1000 Å.

5. The method of claim 1, wherein the cleaning gas comprises hydrogen (H₂) purging gas.

6. The method of claim 5, wherein a flow rate of the hydrogen (H₂) purging gas is more than 2 slm.

7. The method of claim 1, wherein the cleaning gas comprises chlorine containing etchant gas.

8. A method for substrate processing, comprising:
performing an epitaxial deposition process to deposit layers on a surface of a substrate supported on a front surface of a substrate support disposed in an upper volume of a processing chamber; and
performing a coating removal process to remove coating on an inner surface of a lower volume of the processing chamber, wherein the lower volume is on the opposite side of the substrate support from the front surface.

9. The method of claim 8, further comprising:
performing a temperature monitoring process to measure temperature of the inner surface of the lower volume of the processing chamber; and
performing a temperature control process to adjust temperature of the inner surface of the lower volume of the processing chamber, based on the measured temperature.

10. The method of claim 8, wherein the epitaxial deposition process comprises flowing one or more process reactive gases into the upper volume of the processing chamber.

11. The method of claim 10, wherein the one or more process reactive gases comprise a silicon or germanium containing precursor.

12. The method of claim 11, wherein the layers deposited in the epitaxial deposition process comprise more than 2 pairs of alternating layers of silicon (Si) and silicon germanium (SiGe), each layer having a thickness of between 50 Å and 1000 Å.

13. The method of claim 8, wherein the coating removal process comprises flowing hydrogen (H₂) purging gas through the lower volume of the processing chamber.

14. The method of claim 13, wherein a flow rate of the hydrogen (H₂) purging gas is more than 2 slm.

15. The method of claim 8, wherein the coating removal process comprises flowing chlorine containing etchant gas through the lower volume of the processing chamber.

16. A substrate processing system, comprising:
a processing chamber, comprising:
an upper window;
a lower window;
a substrate support disposed between the upper window and the lower window;
a process volume between a front surface of the substrate support and the upper window;
a purge volume between a back surface of the substrate support and the lower window; and
a temperature sensor disposed on the lower window;
a controller comprising instructions that, when executed, cause operations to be conducted, the operations comprising:
performing an epitaxial deposition process to deposit layers on a surface of a substrate supported on the front surface of the substrate support;
performing a coating removal process to remove coating on an inner surface of the lower window;
performing a temperature monitoring process to measure temperature of an inner surface of the lower window; and
performing a temperature control process to adjust temperature of the inner surface of the lower window, based on the measured temperature.

17. The substrate processing system of claim 16, wherein
the epitaxial deposition process comprises flowing one or more process reactive gases into the process volume of the processing chamber,
the one or more process reactive gases comprise a silicon or germanium containing precursor, and
the layers deposited in the epitaxial deposition process comprise more than 2 pairs of alternating layers of silicon (Si) and silicon germanium (SiGe), each layer having a thickness of between 50 Å and 1000 Å.

18. The substrate processing system of claim 16, wherein the processing chamber further comprises:
a purge inlet passage in fluid communication with the purge volume; and
a purge outlet passage in fluid communication with the purge volume.

19. The substrate processing system of claim 18, wherein the coating removal process comprises flowing hydrogen (H₂) purging gas through the purge volume via the purge inlet passage and the purge outlet passage.

20. The substrate processing system of claim 18, wherein the coating removal process comprises flowing chlorine containing etchant gas through the purge volume via the purge inlet passage and the purge outlet passage.
